(19) United States
(12) Patent Application Publication
(10) Pub. No.: US 2026/0049415 A1
(43) Pub. Date: Feb. 19, 2026

(54) PARTICLE MANUFACTURING METHOD AND PARTICLE MANUFACTURING DEVICE

(71) Applicant: KOREA ADVANCED INSTITUTE OF SCIENCE AND TECHNOLOGY, Daejeon (KR)

(72) Inventors: Jungchul LEE, Daejeon (KR); Taeyeong KIM, Daejeon (KR)

(73) Assignee: KOREA ADVANCED INSTITUTE OF SCIENCE AND TECHNOLOGY, Daejeon (KR)

(21) Appl. No.: 19/298,588

(22) Filed: Aug. 13, 2025

(30) Foreign Application Priority Data
Aug. 14, 2024 (KR) 10-2024-0108939

(51) Int. Cl. C30B 29/06; C01B 33/021; C30B 29/60; C30B 31/00; C30B 33/00; C30B 33/02; C30B 33/12

(52) U.S. Cl. CPC C30B 29/06; C01B 33/021; C30B 29/60; C30B 31/00; C30B 33/005; C30B 33/02; C30B 33/12; C01P 2004/32

(57) ABSTRACT

A particle manufacturing method is disclosed. A particle manufacturing method according to one aspect of the present disclosure as a method of forming a spherical particle may include forming a structure for forming a structure of a protruding shape with a material composing of the particle on a first substrate, disposing substrates for disposing the first substrate such that the structure faces downward and disposing a second substrate facing the first substrate below the first substrate, forming a particle for heating and diffusing the structure of the first substrate to from a spherical particle from the diffused material of the structure, and collecting a particle for collecting particles by landing the spherical particles falling from the first substrate on the second substrate.

### CROSS-REFERENCE TO RELATED APPLICATION

The present application claims priority to and the benefit of Korean Patent Application No. 10-2024-0108939, filed on Aug. 14, 2024, in the Korean Intellectual Property Office, the entire content of which is incorporated herein by reference.

### BACKGROUND

### 1. Field

The present disclosure relates to a particle manufacturing method and a particle manufacturing device. More particularly, the present disclosure relates to a particle manufacturing method and a particle manufacturing device for manufacturing a spherical particle of a uniform size.

### 2. Description of the Related Art

Silicon as the second most abundant element on Earth after oxygen is one of most accessible inorganic materials due to its plentiful reserves and cost-effectiveness. Silicon demonstrates distinctive properties when engineered at the nanoscale compared to its ordinary form.

One of key applications of silicon nanoparticles in recent technological advancements is in field of energy storage. Compared to graphite, silicon has a more than tenfold higher specific capacity (graphite: 372 mAh/g, silicon: 4200 mAh/g), making it a promising next-generation anode material for high-capacity lithium-ion batteries. Particularly, according to reported studies, when a size of a silicon particle is smaller than 150 nm, cracking issues occurring during repeated lithiation and dilithiation processes may be mitigated. Accordingly, fabrication of silicon in a nanoparticle form is important.

Another key application field is in field of optics. Silicon nanoparticles having a size range of 100 to 200 nm may be used in applications involving structural coloration due to Mie resonances. In addition, when the size is scaled down to a 1 nm level, the silicon nanoparticles may be used as a photonic material, particularly as a quantum dot.

Among conventional silicon particle manufacturing methods, a top-down method has an advantage in an aspect of quality, such as crystallinity and uniformity. Typically, bulk silicon is fabricated into a nanoparticle through electrochemical etching, mechanical milling, or laser ablation. However, the above methods have common challenges of not only ununiform shapes, wide size distribution, and difficulty in controlling a size, but also limited production capacity.

Among other conventional silicon particle manufacturing methods, a bottom-up method has an advantage in mass production. A silicon nanoparticle is mainly manufactured through thermal decomposition of silane, which is a gaseous precursor, or by reduction of silicon tetrachloride, which is a liquid precursor. However, the above method has challenges in a wide size distribution, difficulty in controlling a size, and generation of by-products.

Among yet other conventional silicon particle manufacturing methods, there is a method through magnesium thermal reduction of a silica nanoparticle. However, this method also has challenges in a wide size distribution of silicon nanoparticles and formation of unreacted silica or magnesium silicide due to incomplete reduction.

### SUMMARY

Embodiments of the present disclosure are to provide a particle manufacturing method and a particle manufacturing device for production of large quantities of particles in a uniform size.

According to one aspect of the present disclosure, as a method of forming a spherical particle, a particle manufacturing method including forming a structure for forming a structure of a protruding shape with a material composing of the particle on a first substrate, disposing substrates for disposing the first substrate such that the structure faces downward and disposing a second substrate facing the first substrate below the first substrate, forming a particle for heating and diffusing the structure of the first substrate to form a spherical particle from the diffused material of the structure, and collecting a particle for collecting particles by landing the spherical particles falling from the first substrate on the second substrate is provided.

Here, the forming a structure may include forming a cylindrical pillar standing on the first substrate.

Here, in the forming a structure, a diameter or an aspect ratio of the cylindrical pillar may be modified to control a diameter of the spherical particle formed in the forming a particle.

Here, the forming a structure may include forming a first cylindrical pillar on the first substrate, oxidizing the first pillar, and forming a second cylindrical pillar having a smaller diameter than the first cylindrical pillar by removing an oxidized layer of the first cylindrical pillar.

In addition, in the forming a structure, a material composing of the particle may include a semiconductor material.

Here, the semiconductor material may include at least any one of silicon (Si), germanium (Ge), gallium arsenide (GaAs), and silicon carbide (SiC).

In addition, the forming a particle may include annealing the structure at a high temperature.

In addition, separating the particle for separating the spherical particle landed on the second substrate from the second substrate may be further included.

Here, the separating the particle may include sliding a blade across a surface of the second substrate to detach the spherical particle.

Meanwhile, according to another aspect of the present disclosure, a particle manufacturing device including a support configured to support a first substrate below which a structure of a protruding shape is formed, a heating unit configured to heat the structure of the first substrate supported by the support, and a collection unit disposed below the support and configured to support a second substrate on which a spherical particle transformed by heating the structure is landed is provided.

Here, a chamber accommodating the support, the heating unit and the collection unit may be further included.

In addition, a blade configured to slide across a surface of the second substrate to detach the spherical particle may be further included.

According to one embodiment of the present disclosure, it becomes possible to manufacture spherical particles in large quantities and in a uniform size

### BRIEF DESCRIPTION OF THE DRAWINGS

The accompanying drawings are included to provide a further understanding of the present disclosure and are incorporated in and constitute a part of this disclosure. The drawings illustrate embodiments of the present disclosure and, together with the description, serve to explain principles of the disclosure. These and/or other features will become apparent and more readily appreciated from the following description of one or more embodiments, taken in conjunction with the accompanying drawings, in which:

FIG. 1 is a flow chart illustrating a particle manufacturing method according to one embodiment of the present disclosure;

FIG. 2 through FIG. 5 are illustrations showing a particle manufacturing method according to one embodiment of the present disclosure;

FIG. 6 and FIG. 7 are exemplary illustrations of formation of a structure in a particle manufacturing method according to one embodiment of the present disclosure;

FIG. 8 is a photograph showing a particle by a particle manufacturing method according to one embodiment of the present disclosure;

FIG. 9 through FIG. 11 are illustrations showing controlling a size of a particle in a particle manufacturing method according to one embodiment of the present disclosure;

FIG. 12 and FIG. 13 are illustrations explaining uniformity of a particle size in a particle manufacturing method according to one embodiment of the present disclosure; and

FIG. 14 and FIG. 15 are illustrations showing a manufacturing device according to another embodiment of the present disclosure.

### DETAILED DESCRIPTION

The terms used in the present disclosure intended to describe a certain embodiment of the present disclosure and not to limit the present disclosure to those terms. Any singular expressions include plural expressions, unless deemed to mean otherwise.

When a component is described to “include” or “comprise” an element, it shall be understood to mean that the component may further include another element, rather than excluding another element, unless otherwise described. Moreover, throughout the specification, when it is described to be “on” an object, it shall be understood to be above or below said object, and not necessarily above said object in a gravitational direction.

When an element is described to be “connected” or “coupled” to another element, it shall include not only the case of said element physically being connected or coupled to the other element but also the case of said element indirectly being connected or coupled to the other element by way of yet another element interposed between said element and the other element.

While terms such as “first” and “second” may be used to describe various elements, these elements shall not be limited by these terms. Rather, these terms are used solely for the purpose of distinguishing one element from another element.

The size and thickness of each element shown in the drawings are illustrated for the convenience of description, and the present disclosure shall not be limited to the illustrated size and thickness.

Hereinafter, an embodiment of a particle manufacturing method and a particle manufacturing device according to the present disclosure will be described with reference to the accompanying drawings. In describing the present disclosure with reference to the accompanying drawings, identical or corresponding elements will be given identical reference numerals and will not be redundantly described.

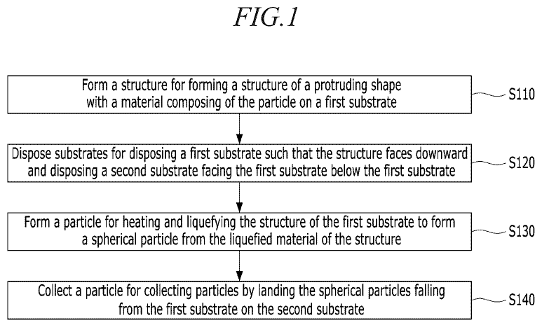

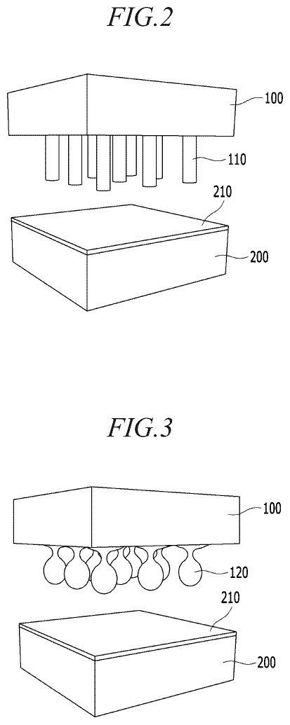

FIG. 1 is a flow chart illustrating a particle manufacturing method according to one embodiment of the present disclosure, and FIG. 2 through FIG. 5 are illustrations showing a particle manufacturing method according to one embodiment of the present disclosure.

Referring to FIG. 1, a particle manufacturing method according to one embodiment of the present disclosure includes forming a structure S110, disposing substrates S120, forming a particle S130, and collecting the particle S140 as forming a spherical particle 120.

In the forming a structure S110, a structure 110 of a protruding shape is formed with a material composing of a particle 120 on a first substrate 100.

The material composing of a particle 120 may include a semiconductor material. Accordingly, by a particle manufacturing method according to the embodiment, a spherical particle 120 may be formed with a semiconductor material. Here, the semiconductor material may include at least one of silicon (Si), germanium (Ge), gallium arsenide (GaAs), and silicon carbide (SiC).

For example, a structure 110 of a protruding shape may be formed with silicon in the embodiment. Accordingly, a single-crystalline silicon particle 120 may be obtained through steps described below. Because a single-crystal is a material consisting of a uniform crystal structure throughout its entire volume, the single-crystalline silicon particle 120 does not have defects, such as a grain boundary, and thus it is advantageous in manufacturing a semiconductor device.

Referring to FIG. 2, forming a structure S110 in the embodiment may include forming a cylindrical pillar on a first substrate 100. The cylindrical pillar may be formed with a structure of standing on the first substrate 100.

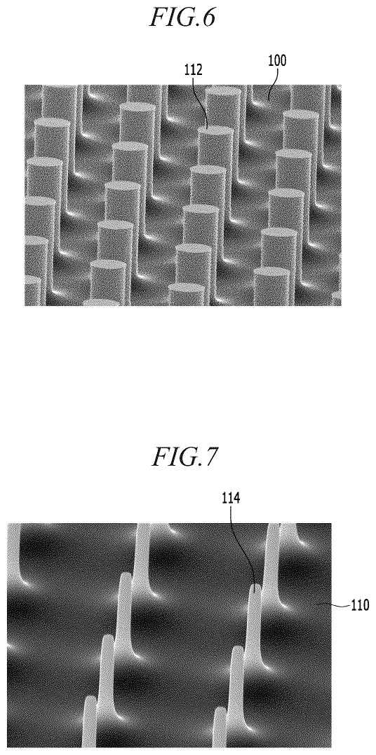

FIG. 6 and FIG. 7 are exemplary illustrations of formation of a structure 100 in a particle manufacturing method according to the embodiment of the present disclosure.

Referring to FIG. 6, a first cylindrical pillar 112 may be formed on the first substrate 100. Here, a plurality of first pillars 112 may be formed on the first substrate 100.

For example, a silicon wafer may be used as the first substrate 100, and a cylindrical silicon pillar may be formed on the silicon wafer. A silicon pillar may be formed on a surface of the silicon wafer through patterning (for example, Near UV (g-line/i-line) Stepper) and etching (for example, anisotropic DRIE (Deep Reactive Ion Etching) process).

Referring to FIG. 7, the first pillar 112 may be oxidized, and an oxidized layer of the first pillar 112 may be removed to form a second cylindrical pillar 114 having a diameter smaller than the first pillar 112.

For example, after oxidization of a surface of the silicon pillar, the oxidized layer may be removed through wet etching. Here, as the oxidization time of the silicon pillar increases, a diameter of the pillar may decrease.

In the embodiment, after formation of the first pillar 112 composed of silicon in a micro scale (e.g., diameter of 1.5 μm) on the silicon wafer, the first pillar 112 may be oxidized, and the oxidized layer may be removed to form a second pillar 114 composed of silicon in a nano scale (e.g., diameter of 100 nm to 490 nm).

In the disposing substrates S120, a first substrate 100 may be disposed such that the structure 110 faces downward. In addition, a second substrate 200 may be disposed to face the first substrate 100 below the first substrate 100.

Referring to FIG. 2, in the disposing substrates of the embodiment, the first substrate 100 may be disposed such that a cylindrical pillar standing on the first substrate 100 faces downward. Here, below the cylindrical pillar of the first substrate 100, the second substrate 200 may be disposed parallel to the first substrate 100 to face the cylindrical pillar.

For example, the silicon wafer may be utilized as the second substrate 200, and an oxidized layer 210 may be formed on an upper surface of the silicon wafer utilized as the second substrate 200. The oxidized layer 210 of the silicon wafer may prevent bonding of the particle to the second substrate 200.

In the forming a particle S130, the structure 110 of the first substrate 100 may be heated to form a spherical particle 120. Upon heating the structure 110 of the first substrate 100, a material composing of the structure 110 may be diffused. Here, a spherical particle 120 may be formed with a material of the diffused structure 110.

For example, the structure 110 may be annealed at a high temperature to form a spherical particle 120. For example, in the embodiment, the annealing may be performed for 100 minutes at a high temperature and a vacuum (1150° C., 2×10⁻⁶ Torr).

Referring to FIG. 3, in the forming a particle 130 of the embodiment, upon annealing the cylindrical silicon pillar at a high temperature, a liquefied silicon material may be formed in a spherical shape due to Rayleigh-Plateau instability.

As the silicon material formed in a spherical shape is suspended upside down from the first substrate 100, it may fall onto the second substrate 200 positioned below due to gravity. Here, the spherical particle 120 does not necessarily refer to a perfectly spherical shape, but rather indicates that the overall shape is generally spherical.

In the collecting the particle S140, the particle 120 is collected by landing the spherical particle 120 falling from the first substrate 100 on the second substrate 200.

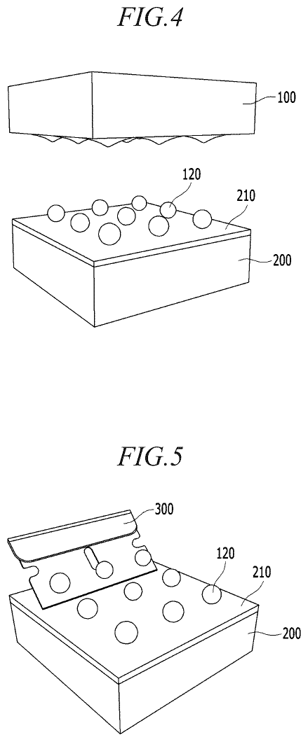

Referring to FIG. 4, in the collecting the particle S140 in the embodiment, the spherical silicon material may fall and land on the oxidized layer 210 of the silicon wafer utilized as the second substrate 200. As a spherical particle 120 is formed respectively on the plurality of first pillars 112, a plurality of particles 120 may be collected together from the second substrate 200. In addition, after falling of the spherical particle 120 from the first substrate 100, the first substrate 100 may be planarized and reused. That is, after planarization of the used first substrate 100, a structure 110 of a protruding shape may be formed again with a material composing of a particle on the first substrate 100.

FIG. 8 is a photograph showing a particle 120 by a particle manufacturing method according to one embodiment of the present disclosure. The portion indicated by a white dot indicates a plurality of particles 120 landed on the second substrate 200.

Referring to FIG. 8, it can be confirmed that a plurality of spherical silicon particles 120 may be simultaneously obtained by a particle manufacturing method according to one embodiment of the present disclosure. Here, the obtained spherical silicon particles 120 may be single-crystalline silicon particles 120 and have a highly uniform size. Through X-ray Diffraction (XRD), it can be confirmed that the silicon particle 120 according to the particle manufacturing method of the embodiment is single-crystalline.

The particle manufacturing method according to the embodiment may further include separating a particle for separating the spherical particle 120 landed on the second substrate 200 from the second substrate 200.

Referring to FIG. 5, in the separating a particle of the embodiment, a blade 300 may be utilized to separate the spherical particle 120 from the second substrate 200. For example, the spherical particle 120 may be detached by sliding an edge of the blade 300 across a surface of the second substrate 200. The spherical particle 120 separated by the blade 300 may be obtained in a form of uniform powder.

Particularly, in the particle manufacturing method according to the embodiment, a size of the particle 120 collected from the second substrate 200 may be controlled by controlling a size or a shape of the structure 110 formed on the first substrate 100.

In the embodiment, a diameter or an aspect ratio of the cylindrical pillar formed on the first substrate 100 may be modified to control a diameter of the spherical particle 120.

Particularly, in the forming a structure S110, a diameter or an aspect ratio of the cylindrical pillar may be modified. Upon modification of a diameter or an aspect ratio of the cylindrical pillar, a diameter of the spherical particle 120 formed in the forming a particle S130 may be modified. Therefore, a diameter of the spherical particle 120 may be controlled by modifying a diameter or an aspect ratio of the cylindrical pillar.

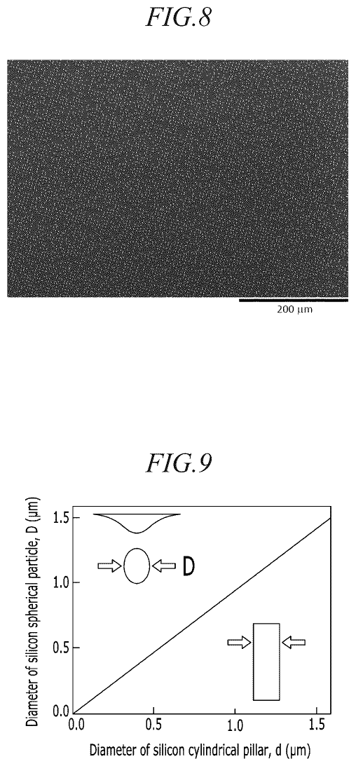

FIG. 9 through FIG. 11 are illustrations showing controlling a size of a particle 120 in a particle manufacturing method according to one embodiment of the present disclosure.

Referring to FIG. 9, a change in a diameter of the spherical particle 120 according to modification of a diameter of the cylindrical pillar in the embodiment may be simulated, and a linear relationship between the diameter of the cylindrical pillar and the diameter of the spherical particle 120 may be predicted. Here, it is assumed that the aspect ratio at which the spherical particle 120 is formed is maintained at 3.

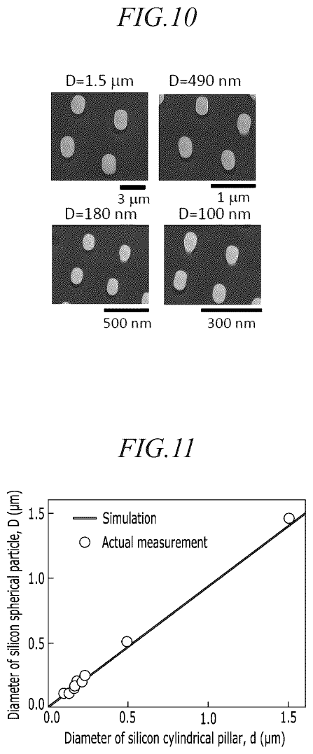

Referring to FIG. 10 and FIG. 11, it can be confirmed that the silicon particle 120 is formed with a size deviation of less than 5% from the simulated prediction.

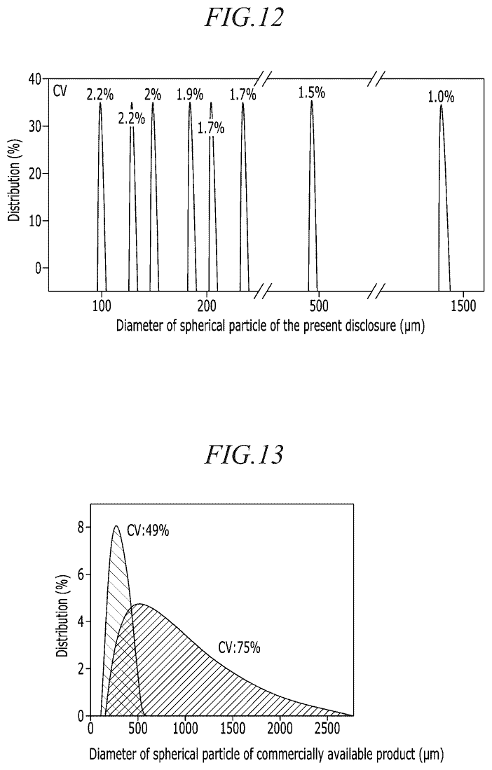

FIG. 12 and FIG. 13 are illustrations explaining uniformity of a size of a particle 120 in a particle manufacturing method according to one embodiment of the present disclosure. FIG. 12 shows uniformity of a size of a particle 120 in a particle manufacturing method of the embodiment, and FIG. 13 shows uniformity of a size of a particle 120 in a commercially available product.

Sizes of a silicon particle 120 manufactured through the particle manufacturing method of the embodiment and a silicon particle 120 of a commercially available product are measured by dispersing the particle 120 in methanol and analyzing the particle size using Dynamic Light Scattering (DLS).

Referring to FIG. 12, it can be confirmed that a spherical silicon particle 120 formed through a particle manufacturing method of the embodiment has a uniform size with a coefficient of variation (CV) of less than 2.2% over a diameter range from 100 nm and 1.5 μm.

Referring to FIG. 13, compared to the embodiment, it can be confirmed that a size of a particle 120 in a commercially available product exhibits a coefficient of variation greater than or equal to 49%.

Meanwhile, a particle manufacturing device 1000 according to another aspect of the present disclosure is provided.

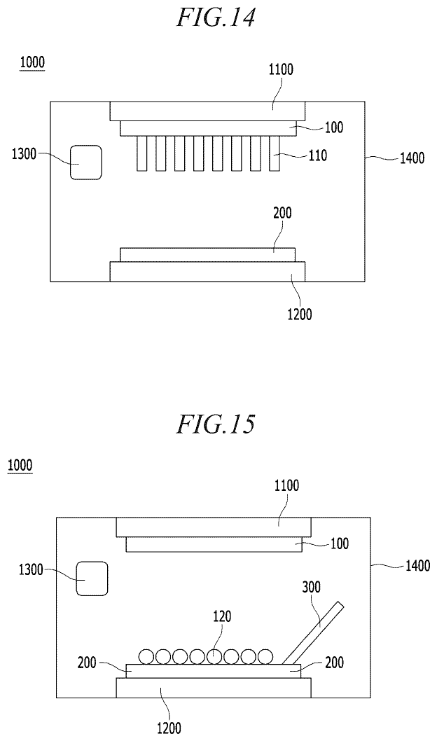

FIG. 14 and FIG. 15 are illustrations showing a manufacturing device 1000 according to another embodiment of the present disclosure.

Referring to FIG. 14 and FIG. 15, a particle manufacturing device 1000 according to another aspect of the present disclosure includes a support 1100, a heating unit 1300, and a collection unit 1200.

The support 1100 may be configured to support a first substrate 100. A structure 110 of a protruding shape may be formed below the first substrate 100, and the support 1100 may be configured to support the first substrate 100 such that the structure 110 of the first substrate 100 faces downward.

Referring to FIG. 14, while the structure 110 is formed on one side of the first substrate 100, the support 1100 of the embodiment may be configured to support the first substrate 100 by attaching to the opposite side of the first substrate 100 from above, for example, by vacuum suction. Accordingly, the one side of the first substrate 100 may face downward, such that the structure 110 of the first substrate 100 faces downward.

The heating unit 1300 may heat the structure 110 of the first substrate 100 supported by the support 1100.

Referring to FIG. 14, the heating unit 1300 of the embodiment may be disposed in a space together with the first substrate 100 and configured to heat the structure 110 of the first substrate 100. Upon heating the structure 110 of the first substrate 100, a material composing of the structure 110 may be diffused. Here, the spherical particle 120 may be formed with the diffused material of the structure 110.

For example, the heating unit 1300 may include a heater configured to anneal the structure 110 at a high temperature. Accordingly, a material composing of the structure 110 may be diffused to form the spherical particle 120.

The collection unit 1200 may be disposed below the support 1100 and configured to support a second substrate 200 configured to collect a particle 120 falling from the first substrate 100.

Referring to FIG. 14, the collection unit 1200 of the embodiment may be configured to support a second substrate 200 from below. The second support 200 may be disposed below the first substrate 100 to face the first substrate 100. Accordingly, upon formation of the spherical particle 120 by heating and diffusing the structure 110 of the first substrate 100, the spherical particle 120 formed on the first substrate 100 may fall onto the second substrate 200 due to gravity.

The particle manufacturing device 1000 according to the embodiment may further include a chamber 1400 configured to accommodate the support 1100, the heating unit 1300, and the collection unit 1200. Accordingly, an environmental condition, such as temperature and pressure, within the chamber may be readily controlled to facilitate formation of the particle 120. For example, in the embodiment, annealing may be performed for 100 minutes at a high temperature and high vacuum (1150° C., 2×10⁻⁶ Torr).

In addition, referring to FIG. 15, the particle manufacturing device 1000 according to the embodiment may further include a blade 300 configured to slide across a surface of the second substrate 200 to detach the spherical particle 120. For example, the spherical particle 120 may be detached by sliding an edge of the blade 300 across a surface of the second substrate 200. The spherical particle 120 separated by the blade 300 may be obtained in a uniform powder form.

Hitherto, while a preferred embodiment of the present disclosure has been described, any one of ordinary skill in the art to which the present disclosure pertains shall appreciate that any variety of permutations and/or modifications of the described embodiment are possible, without departing from the technical ideas of the present disclosure described in the appended claims, by supplementing, modifying, deleting or adding certain elements, and that such permutations and/or modifications are included in the claims of the present disclosure.

### DESCRIPTION OF ELEMENTS

100: first substrate
110: structure
112: first pillar
114: second pillar
120: particle
200: second substrate
300: blade
1000: particle manufacturing device
1100: support
1200: collection unit
1300: heating unit
1400: chamber

What is claimed is:

1. A particle manufacturing method as a method of forming a spherical particle, the method comprising:
forming a structure for forming a structure of a protruding shape with a material composing of the particle on a first substrate;
disposing substrates for disposing the first substrate such that the structure faces downward and disposing a second substrate facing the first substrate below the first substrate;
forming a particle for heating and diffusing the structure of the first substrate to form a spherical particle from the diffused material of the structure; and
collecting a particle for collecting particles by landing the spherical particles falling from the first substrate on the second substrate.

2. The particle manufacturing method of claim 1,
wherein the forming a structure comprises forming a cylindrical pillar standing on the first substrate.

3. The particle manufacturing method of claim 2,
wherein in the forming a structure, a diameter or an aspect ratio of the cylindrical pillar is modified to control a diameter of the spherical particle formed in the forming a particle.

4. The particle manufacturing method of claim 3,
wherein the forming a structure comprises:
forming a first cylindrical pillar on the first substrate;
oxidizing the first pillar; and
forming a second cylindrical pillar having a smaller diameter than the first cylindrical pillar by removing an oxidized layer of the first cylindrical pillar.

5. The particle manufacturing method of claim 1,
wherein in the forming a structure, the material composing of the particle comprises a semiconductor material.

6. The particle manufacturing method of claim 5,
wherein the semiconductor material comprises at least any one of silicon (Si), germanium (Ge), gallium arsenide (GaAs), and silicon carbide (SiC).

7. The particle manufacturing method of claim 1,
wherein the forming a particle comprises annealing the structure at a high temperature.

8. The particle manufacturing method of claim 1, the method further comprising separating the particle for separating the spherical particle landed on the second substrate from the second substrate.

9. The particle manufacturing method of claim 8,
wherein the separating the particle comprises sliding a blade across a surface of the second substrate to detach the spherical particle.

10. The particle manufacturing method of claim 1, the method further comprising, after the collecting a particle, planarizing the first substrate for reuse to re-form a structure of a protruding shape with a material composing of the particle on the first substrate.

11. A particle manufacturing device comprising:
a support configured to support a first substrate below which a structure of a protruding shape is formed;
a heating unit configured to heat the structure of the first substrate supported by the support; and
a collection unit disposed below the support and configured to support a second substrate on which a spherical particle transformed by heating the structure is landed.

12. The particle manufacturing device of claim 11, further comprising a chamber accommodating the support, the heating unit and the collection unit.

13. The particle manufacturing device of claim 11, further comprising a blade configured to slide across a surface of the second substrate to detach the spherical particle.
